(19) United States
(12) Patent Application Publication
(10) Pub. No.: US 2017/0194485 A1
(43) Pub. Date: Jul. 6, 2017

(54) SPLIT-GATE SUPERJUNCTION POWER TRANSISTOR

(71) Applicant: Polar Semiconductor, LLC, Bloomington, MN (US)

(72) Inventors: Christopher Smith, Richfield, MN (US); Steven Kosier, Lakeville, MN (US); Peter West, Minneapolis, MN (US)

(21) Appl. No.: 14/989,044

(22) Filed: Jan. 6, 2016

(51) Int. Cl. H01L 29/78; H01L 29/06; H01L 29/40; H01L 29/08; H01L 29/66; H01L 21/265; H01L 29/423; H01L 29/10

(52) U.S. Cl. CPC H01L 29/7813; H01L 29/4236; H01L 29/0634; H01L 29/0696; H01L 29/1095; H01L 29/0856; H01L 29/66734; H01L 21/26513; H01L 29/407

(57) ABSTRACT

A power metal-oxide semiconductor field-effect transistor (MOSFET) and method of manufacturing thereof, includes a trench, a trench doping and a pillar doping region. The trench is etched into a silicon layer that includes a gate structure disposed therein. The trench doping is implanted in the silicon layer vertically below the trench and has an opposite doping type than the silicon layer. The pillar doping region is implanted in the silicon layer vertically below, and spaced from the trench doping. The pillar doping region has a same doping type as the trench doping.

### BACKGROUND

The present invention relates generally to semiconductor devices, and in particular to power trench metal-oxide-semiconductor field-effect transistors (MOSFETs).

Power MOSFETS are a type of MOSFET that are designed to handle significant power levels. These devices are designed to tolerate high voltages at the transistor terminals. For these high voltage devices, the on-resistance is determined at least in part by the voltage sustaining layer. Additionally, the breakdown voltage of the device mainly depends on the doping concentration and the thickness of the layer. The lower the doping concentration and/or the larger the thickness of the layer, the higher the breakdown voltage. However, the higher breakdown voltage comes with a larger on-resistance (or on-voltage). It is desirable to provide a higher breakdown voltage while limiting the on-resistance and the gate capacitance of the device.

### SUMMARY

A power metal-oxide semiconductor field-effect transistor (MOSFET) includes a trench, a trench doping and a pillar doping region. The trench is etched into a silicon layer that includes a gate structure disposed therein. The trench doping is implanted in the silicon layer vertically below the trench and has an opposite doping type than the silicon layer. The pillar doping region is implanted in the silicon layer vertically below, and spaced from the trench doping. The pillar doping region has a same doping type as the trench doping.

A method of manufacturing a power metal-oxide-semiconductor field-effect transistor (MOSFET) includes forming a doping pillar in a silicon layer, etching a trench in the silicon layer above the doping pillar; implanting a doping region below the trench and spaced from the doping pillar; and depositing a first gate structure within the trench.

A power transistor includes a plurality of trenches etched into a silicon layer and a plurality of doping pillars. Each of the plurality of trenches includes a gate structure and a field structure disposed therein. The plurality of doping pillars are each implanted in the silicon layer vertically below a respective one of the plurality of trenches. Each of the plurality of doping pillars is doped opposite a type of the silicon layer.

### BRIEF DESCRIPTION OF THE DRAWINGS

FIG. 1 is a cross-sectional view illustrating a prior art planar superjunction power transistor.

FIG. 2 is a cross-sectional view illustrating a split-gate superjunction power transistor.

FIG. 3 is a flowchart illustrating a method of manufacturing a split-gate superjunction power transistor.

### DETAILED DESCRIPTION

A split-gate superjunction power metal-oxide-semiconductor field-effect transistor (MOSFET) is disclosed herein that includes a trench with at least one gate structure, a trench implant vertically below the trench, and a doping pillar vertically beneath the trench implant. The doping pillar is spaced from the trench implant and doped of the same type as the trench implant. The doping pillar may be formed, for example, by implanting doping regions into epitaxial formed silicon layers. For example, four epitaxial layers may be formed such that within each layer, a doping region is formed, aligned with, and in contact with the previous layer to form the doping pillar.

By implanting a trench implant in conjunction with the doping pillar, the split-gate superjunction power MOSFET may be manufactured, for example, using fewer epitaxial layers while achieving a similar breakdown voltage to that of prior art superjunction transistors. This may reduce the overall cost and complexity of manufacture of the power MOSFET. Using the split-gate trench may reduce the on-resistance and gate capacitance of the transistor. Lower gate capacitance may be advantageous in systems, for example, with high switching frequencies such as switching-mode power supplies.

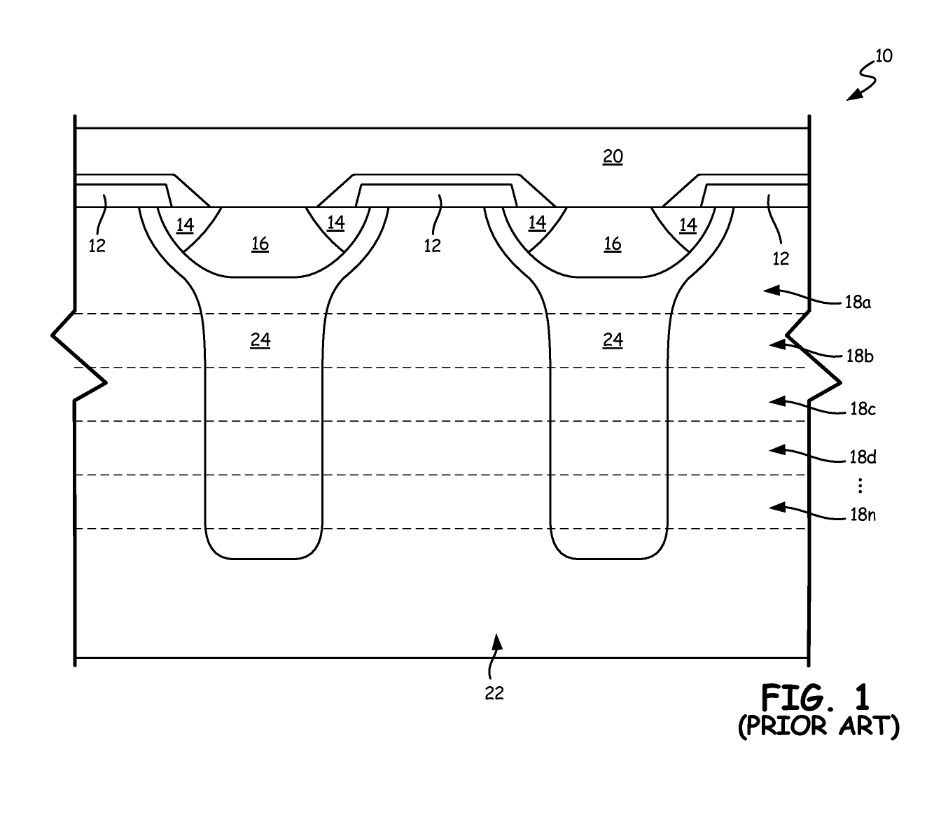

FIG. 1 is a cross-sectional view illustrating a prior art planar superjunction power transistor 10. Planar superjunction power transistor 10 may be a metal-oxide-semiconductor field-effect transistor (MOSFET). Transistor 10 includes gate 12, source doping regions 14, body doping regions 16, epitaxial layers 18a-18n, topside metal 20 and drain 22. Body doping regions 16 each include doping pillar 24. Source doping regions 14 and drain 22 may be doped either both n-type or p-type depending on the desired transistor species, with body doping regions 16 being doped opposite the type of source doping regions 14 and drain 22.

Power transistor 10 may be implemented to accommodate voltages, for example, of up to, and greater than, 600 volts. In the embodiment shown in FIG. 1, power transistor 10 may be configured to have a breakdown voltage of, for example, 620 volts. Transistor 10 may have been formed using five epitaxial layers 18a-18n, for example, to achieve this breakdown voltage. Doping pillar 24 may be formed during the forming of epitaxial layers 18a-18n. Doping pillar 24 is doped opposite the type of drain 22. Doping pillars 24 were added to the design to contain the electric field within the epitaxial layer.

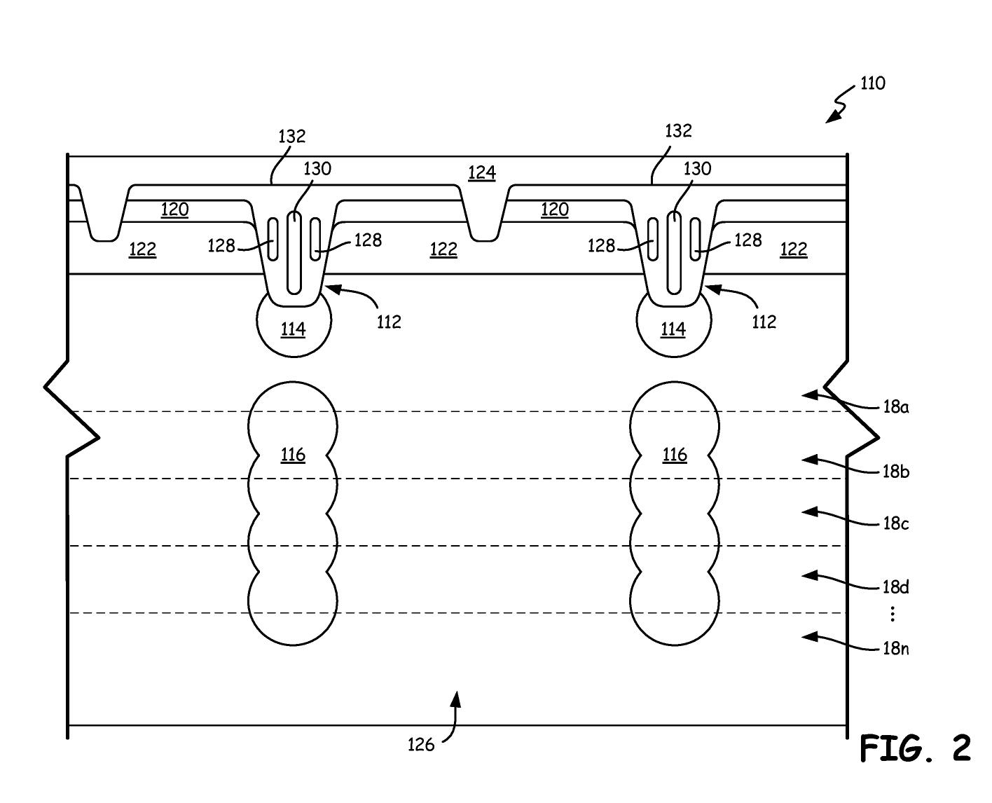

FIG. 2 is a cross-sectional view illustrating split-gate superjunction power transistor 110. Split-gate superjunction power transistor 110 may be a metal-oxide-semiconductor field-effect transistor (MOSFET). Transistor 110 includes trenches 112, trench implants 114, doping pillars 116, epitaxial layers 118a-118n, source doping regions 120, body doping regions 122, topside metal 124 and drain 126. In the embodiment shown in FIG. 2, gate structures 128 and field structure 130 are deposited within trench 112 and are surrounded by oxide 132. Source doping regions 120 and drain 126 may be doped either both n-type or p-type depending on the desired transistor species, with body doping regions 122 being doped opposite the type of source doping regions 120 and drain 126. Drain 126 may be implemented using an n-type substrate, for example, on a backside metal layer. Drain 126 may be doped, for example, with a high doping concentration (n⁺).

Split-gate superjunction transistor 110 may be manufactured through the deposition of epitaxial layers 118a-118n vertically above the n⁺ substrate of drain 126. In the embodiment shown in FIG. 2, epitaxial layer 118n is formed first above drain 126, followed by 118c, 118b and 118a. Any number of epitaxial layers 118a-118n may be formed based upon the desired breakdown voltage of transistor 110. For example, four epitaxial layers 118a-118n may be utilized to achieve a breakdown voltage for transistor 110 of greater than 650 volts. Epitaxial layers 118a-118n may be doped the same type as drain 126 but may have a lighter doping (n⁻), for example.

Doping pillar 116, which may be doped opposite the doping type of drain 126, may be implanted during the forming of epitaxial layers 118a-118n. During the manufacturing process, each epitaxial layer 118a-118n may include a doping implant for each doping pillar 116. These doping implants are configured to align with the doping implant of the previous epitaxial layer 118a-118n. A doping implant may also be included in the substrate as illustrated in FIG. 2. These implants combine to form doping pillars 116 in split-gate superjunction transistor 110. In the embodiment shown in FIG. 2, doping pillars 116 are floating pillars that are spaced from trench implants 114.

Trenches 112 may be etched into epitaxial layer 118a using, for example, a hard mask formed on the top of epitaxial layer 118a, or any other method of forming trenches in silicon layers. Trenches 112 are manufactured to align with doping pillars 116. Trenches 112 include gate structures 128 and field structures 130 disposed therein. Field structure 130 may be biased, for example, such that field structures 130 in adjacent trenches effectively shield the portion of epitaxial layers 118a-118n between adjacent trenches 112 from excessive voltage.

Trench implants 114 may be implanted vertically below each respective trench 112 following the etching of trenches 112. Any method of achieving the desired doping for the implant in epitaxial layer 118a may be utilized. Trench implants 114 may be doped the same type as doping pillar 116 with a lighter doping concentration (p⁻), for example. Following implantation of trench implants 114, gate structures 128 and field structures 130 may be deposited within respective trenches 112 using any known method. For example, an initial oxide layer may be deposited within trench 112, followed by deposition of gate structures 128 and field structures 130.

Additionally, body doping regions 122 may be implanted and driven to a desired depth within epitaxial layer 118a using any known method. Subsequently, source doping regions 120 may also be implanted into epitaxial layer 118 using any known method. Oxide layer 132 may then be deposited, for example, over epitaxial layer 118a, vertically above source doping regions 120, gate structures 128, and field structures 130. Topside metal 124 may be formed over oxide layer 132. In the embodiment illustrated in FIG. 2, a contact may be etched into epitaxial layer 118a such that topside metal 124 is in contact with both source doping regions 120 and body doping regions 122. In other embodiments, source doping regions 120 and body doping regions 122 may be configured such that no etched contact may be necessary.

Trench implant 114 in conjunction with doping pillar 116 act together to perform a similar function to that of doping pillar 24 of transistor 12 of FIG. 1. Trench implant 114 and doping pillar 116 act to contain the electric field within epitaxial layers 118a-118n. By utilizing trench implant 114 in conjunction with doping pillar 116, the same, or greater, breakdown voltage may be achieved for transistor 110 as that of transistor 10 while requiring fewer epitaxial layers 118a-118n.

For example, transistor 10, as illustrated in FIG. 1, may include five epitaxial layers 18a-18n while having a breakdown voltage of 620 volts. Transistor 110, as illustrated in FIG. 2, may include four epitaxial layers while having a breakdown voltage of 684 volts. Therefore, transistor 110 provides a greater breakdown voltage while requiring fewer epitaxial layers 118a-118n, which may reduce the time and cost required to manufacture transistor 110.

Doping pillar 116 is also utilized in the drift region of transistor 110 in order to reduce the on-resistance of the device, for example. In planar transistors, the breakdown voltage may be determined based upon the doping and thickness of the drift region. Therefore, a thick, lightly doped epitaxial layer was needed to achieve the higher breakdown voltages. However, with higher breakdown voltages came higher on-resistances. By utilizing doping pillar 116 in conjunction with trench implant 114 to contain the electric field, greater breakdown voltages may be achieved while reducing the on-resistance of transistor 110.

An additional advantage of split-gate superjunction power transistor 110 over planar transistor 10 is the split-gate configuration. The shorter gate length of split-gate superjunction power transistor 110 achieved by the split-gate configuration facilitates a lower gate capacitance for the device than that of planar superjunction transistor 10. The gate capacitance of split-gate superjunction power transistor 110 may be on the order of ten percent that of the gate capacitance of planar superjunction transistor 10, for example. This may be particularly useful in systems which have high switching frequencies for split-gate superjunction power transistor 110.

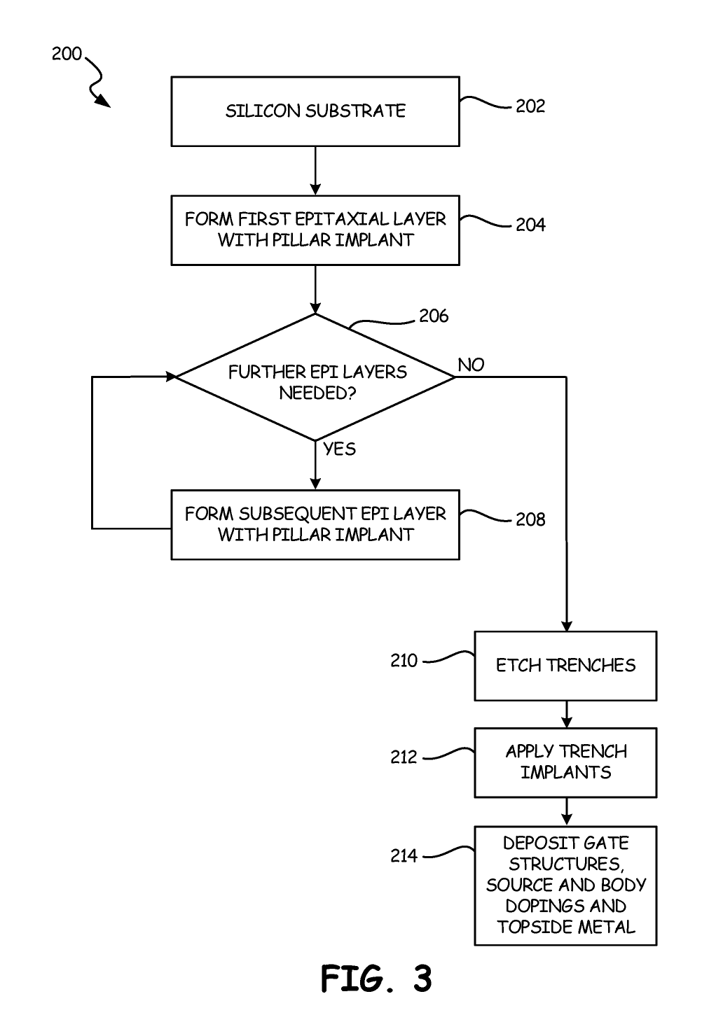

With continued reference to FIG. 2, FIG. 3 is a flowchart illustrating method 200 of manufacturing split-gate superjunction power transistor 110. At step 202, a base substrate that is n-type, for example, may be provided for drain 126. The base substrate may be connected to a backside metal and have a high doping concentration (n⁺). A doping region may be implanted into the substrate as an initial implant for respective doping pillars 116.

At step 204, a first epitaxial layer 118n is formed on the substrate. The epitaxial layer 118n may be doped the same as drain 126 (n-type), for example. A doping region that is opposite the doping type of epitaxial layer 118n and drain 126 may be implanted in epitaxial layer 118n for each respective doping pillar 116. This implant is aligned with any respective implants in the substrate layer for doping pillars 116.

At step 206 it is determined if any further epitaxial layers 118a-118n are to be formed. If so, method 200 proceeds to step 208. If not, method 200 proceeds to step 210. At step 208, subsequent epitaxial layers 118a-118n are deposited on the previous epitaxial layer 118a-118n. For each epitaxial layer 118a-118 that is deposited, further p-type dopings, for example, are implanted within the respective epitaxial layer 118a-118n and aligned with the previous epitaxial layer 118a-118n to form doping pillar 116. Following step 208, method 200 returns to step 206 to determine if any further epitaxial layers 118a-118n remain to be deposited. In the embodiment illustrated in FIG. 2, four epitaxial layers 118a-118n may be utilized to achieve a breakdown voltage of 684 volts, for example.

At step 210, trenches 112 are etched into epitaxial layer 118a using any known method. For example, a hard mask may be formed on the final epitaxial layer 118a and utilized to etch trenches 112. Trenches 112 may be aligned such that each trench 112 aligns with a respective doping pillar 116. Additional processing may be utilized to remove any masks that are utilized to etch trenches 112.

At step 212, trench implant 114 may be implanted at the base of trenches 112 as a p-type implant, for example. Trench implant 114 is implanted vertically aligned with, and spaced from, doping pillar 114. While doped the same type (e.g., p-type), trench implant 114 may be doped lighter (e.g., p⁺) than the doping of doping pillar 114. Trench implant 114 and doping pillar 116 act to contain the electric field within epitaxial layers 118a-118n.

At step 214, source doping regions 120, body doping regions 122, gate structures 128, field structures 130 and topside metal 124 are deposited/implanted using any known methods. Utilizing method 200 allows split-gate superjunction power transistor 110 to be manufactured using fewer epitaxial layers than prior art power MOSFETs while maintaining a similar, or greater breakdown voltage.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A power metal-oxide semiconductor field-effect transistor (MOSFET) comprising:
a first trench etched into a silicon layer, the first trench having a first gate structure and a first field structure disposed therein;
a second trench etched into the silicon layer, the second trench having a second gate structure and a second field structure disposed therein;
a body doping and a source doping implanted in the silicon layer adjacent to the first trench;
a first trench doping implanted in the silicon layer vertically below the first field structure, wherein the first trench doping has only an opposite doping type than the silicon layer and is spaced from the body doping;
a second trench doping implanted in the silicon layer vertically below the second field structure, wherein the second trench doping has only an opposite doping type than the silicon layer and is spaced from the body doping;
a first pillar doping region implanted in the silicon layer vertically below, and spaced from the first trench doping, wherein the first pillar doping region has only a same doping type as the first trench doping; and
a second pillar doping region implanted in the silicon layer vertically below, and spaced from the second trench doping, wherein the second pillar doping region has only a same doping type as the second trench doping; and
wherein the silicon layer between the first and second pillar doping regions and below the body doping has only an opposite doping type to the first and second pillar doping regions.

2. The power MOSFET of claim 1, wherein the first pillar doping region comprises a plurality of doping regions implanted into a plurality of epitaxial layers making up the silicon layer.

3. The power MOSFET of claim 2, wherein the plurality of epitaxial layers comprises four epitaxial layers.

4. The power MOSFET of claim 3, wherein the power MOSFET is configured to have a reverse breakdown voltage greater than 620 volts.

5. The power MOSFET of claim 1, further comprising:
a third gate structure disposed in the first trench; and
wherein the field structure is disposed in the first trench between the first and third gate structures.

6-7. (canceled)

8. A method of manufacturing the power metal-oxide-semiconductor field-effect transistor (MOSFET) of claim 1, the method comprising:
forming the silicon layer that includes the first pillar doping region;
etching the first trench in the silicon layer vertically above the first pillar doping region;
implanting the first trench doping vertically below, and vertically aligned with, the first trench, wherein the first trench doping is spaced vertically from the first pillar doping region; and
depositing the first gate structure within the first trench.

9. The method of claim 8, wherein forming the silicon layer comprises:
forming a plurality of epitaxial layers, each with a respective one of a plurality of pillar dopings.

10. The method of claim 9, wherein forming the plurality of epitaxial layers comprises:
forming a first epitaxial layer with a first pillar doping;
forming a second epitaxial layer with a second pillar doping aligned vertically and in contact with the first pillar doping;
forming a third epitaxial layer with a third pillar doping aligned vertically and in contact with the second pillar doping; and
forming a fourth epitaxial layer with a fourth pillar doping aligned vertically and in contact with the third pillar doping, wherein the first, second, third and fourth pillar dopings form the first pillar doping region.

11. The method of claim 8, wherein depositing the first gate structure within the first trench comprises:
depositing the first field structure within the first trench; and
depositing the first gate structure and a third gate structure on opposite sides of the field structure.

12. The method of claim 8, further comprising:
implanting the body doping region and the source doping region in the silicon layer and aligned with the first gate structure.

13. The method of claim 12, further comprising forming a topside metal layer over the silicon layer and the first trench.

14. A power transistor comprising:
a plurality of trenches etched into a silicon layer, wherein each of the plurality of trenches includes a first gate structure and a first field structure disposed therein;
a body doping and a source doping implanted in the silicon layer adjacent to the plurality of trenches;
a plurality of doping pillars, each only implanted in the silicon layer vertically below, and spaced from, a respective one of the plurality of trenches, wherein each of the plurality of doping pillars is only doped opposite a type of the silicon layer;
a plurality of trench implants doped only a same type as the plurality of doping pillars and spaced from the body doping, wherein each of the trench implants is implanted vertically below a respective one of the plurality of trenches, and positioned vertically above, and spaced from, a respective one of the plurality of doping pillars; and
wherein the silicon layer between each of the plurality of doping pillars and below the body doping is only doped an opposite type to the plurality of doping pillars.

15-16. (canceled)

17. The power transistor of claim 14, wherein the silicon layer comprises four epitaxial layers.

18. The power transistor of claim 17, wherein the four epitaxial layers are doped n-type, the plurality of doping pillars are doped p-type, and the plurality of trench implants are doped p-type.

19. The power transistor of claim 17, wherein the four epitaxial layers are formed on a silicon substrate.

20. The power transistor of claim 17, wherein the power transistor is configured to have a breakdown voltage greater than 620 volts.
